(19) United States
(12) Patent Application Publication
(10) Pub. No.: US 2026/0161936 A1
(43) Pub. Date: Jun. 11, 2026

(54) NEUROMORPHIC DEVICE HAVING THREE-DIMENSIONAL STRUCTURE AND MANUFACTURING METHOD THEREOF

(71) Applicant: Seoul National University R&DB foundation, Seoul (KR)

(72) Inventors: Sangbum Kim, Seoul (KR); Minsik Yoon, Seoul (KR); Donghoon Kang, Seoul (KR)

(21) Appl. No.: 18/725,275

(22) PCT Filed: Dec. 20, 2023
(86) PCT No.: PCT/KR2023/021083

§ 371 Date: Jun. 28, 2024

(30) Foreign Application Priority Data
Mar. 10, 2023 (KR) 10-2023-0032009

(51) Int. Cl. G06N 3/065; H10B 63/00; H10N 70/00

(52) U.S. Cl. CPC G06N 3/065; H10B 63/24; H10N 70/826

(57) ABSTRACT

Disclosed is a neuromorphic device having a three-dimensional structure capable of equilibrium propagation neuromorphic calculation, including a plurality of synapse blocks each having a three-dimensional structure including a plurality of vertical phase change memory units, wherein the vertical phase change memory unit includes a first vertical structure including a first vertical electrode and a phase change material layer surrounding at least a portion of the first vertical electrode, and a plurality of first electrode layers spaced apart from each other in a vertical direction while contacting an outer peripheral surface of the first vertical structure, a plurality of connection members for electrically connecting the plurality of synapse blocks to each other, and a neuron circuit portion connected between the plurality of synapse blocks and including an ovonic threshold switching (OTS) device.

### TECHNICAL FIELD

The present invention relates to electronic devices and their manufacturing methods and applications, and more particularly, to neuromorphic devices and their manufacturing methods and applications.

### BACKGROUND ART

As the scaling down of transistors reaches its limit, the neuromorphic computing system is receiving a lot of attention as a new concept which may overcome the limitations of the existing von Neumann type computer system. A neuromorphic computing is a technology which implements artificial intelligence behavior by imitating the human brain in hardware. Based on the fact that the human brain performs very complex functions but consumes only about 20 W of energy, neuromorphic computing mimics the human brain structure itself and perform artificial intelligence operations such as much more superior association, reasoning, and recognition capabilities as compared to existing von Neumann computing with ultra-low power.

The neuromorphic system which operates such neuromorphic computing is composed of numerous neurons (neuron devices) and synapses (synapse devices), just like the human brain, and includes additional circuits for signal processing and transmission. Synapses remember the connection strength (weight) according to the correlation of spikes expressed by neurons, and in some cases, adjust the connection strength through strengthening/increasing (potentiation) and suppressing/decreasing (depression) processes. At this time, the connection strength may be expressed as the electrical conductance of the synapse. As a synapse device, a device based on RRAM (resistive random access memory) or memristors has been widely studied, and recently, a synapse device based on MOSFET (a metal-oxide-semiconductor field-effect transistor) are also being studied.

Numerous synapses which make up a neuromorphic system may be connected to other components such as neurons and additional circuits for parallel computation in a complicated manner. In addition, in order to use a memory array for artificial intelligence calculations, a digital-to-analog converter (DAC) to convert digital signals into analog signals and an analog-to-digital converter (ADC) to convert analog signals to digital signals may be shared between memory arrays. Therefore, problems arise in which data processing time and energy/power consumption increase due to the use of DAC and ADC and repetitive movement of data and signals.

Meanwhile, equilibrium propagation, a neuromorphic learning algorithm, is an algorithm having analog characteristics and has an advantage that an ADC circuit and a DAC circuit for converting data in the neuromorphic calculation process are not required. However, in order to implement hardware capable of performing the equilibrium propagation algorithm, programmable resistance devices for synapses and antiparallel diodes for adding nonlinearity to the network are required. However, there are various technological problems and difficulties in manufacturing a network device with a complex connection structure including the above-mentioned programmable resistance devices and anti-parallel diodes. In addition, when producing a neuromorphic system in a three-dimensional structure, there are various limitations and problems in producing a network structure connecting synapse devices and neuron devices.

### DISCLOSURE OF THE INVENTION

### Technical Problem

The technological object to be achieved by the present invention is to provide a neuromorphic device having a three-dimensional structure capable of equilibrium propagation neuromorphic calculation.

In addition, the technological object to be achieved by the present invention is to provide a neuromorphic device having a three-dimensional structure which may implement high integration, may simplify a configuration of a neuron circuit portion, and may be easily manufactured by connecting synapse devices and a neuron circuit portion.

In addition, the technological object to be achieved by the present invention is to provide a neuromorphic device having a three-dimensional structure which may perform efficient data processing for a predetermined input data such as image data.

In addition, the technological object to be achieved by the present invention is to provide a manufacturing method of the above-described neuromorphic device.

The objects to be solved by the present invention are not limited to the problems mentioned above, and other objects not mentioned will be understood by those skilled in the art from the description below.

### Technical Solution

According to one embodiment of the present invention, there is provided a neuromorphic device having a three-dimensional structure capable of equilibrium propagation neuromorphic calculation, comprising: a plurality of synapse blocks each having a three-dimensional structure including a plurality of vertical phase change memory units, wherein the vertical phase change memory unit includes a first vertical structure including a first vertical electrode and a phase change material layer surrounding at least a portion of the first vertical electrode, and a plurality of first electrode layers spaced apart from each other in a vertical direction while contacting an outer peripheral surface of the first vertical structure; a plurality of connection members for electrically connecting the plurality of synapse blocks to each other; and a neuron circuit portion connected between the plurality of synapse blocks and including an ovonic threshold switching (OTS) device.

In each of the plurality of synapse blocks, the plurality of vertical phase change memory units may be arranged to form a plurality of rows and a plurality of columns.

The neuron circuit portion may include a vertical neuron device unit.

The vertical neuron device unit may include a second vertical electrode, a second vertical structure including an ovonic threshold switching (OTS) material layer surrounding at least a portion of the second vertical electrode, and a plurality of second electrode layers spaced apart from each other in a vertical direction while contacting with an outer peripheral surface of the second vertical structure.

Each of the plurality of first electrode layers of the vertical phase change memory unit may be electrically connected to each of the plurality of second electrode layers of the vertical neuron device unit corresponding thereto.

Each of the plurality of first electrode layers of the vertical phase change memory unit may be connected to each of the plurality of second electrode layers of the corresponding vertical neuron device unit to form one body.

The plurality of synapse blocks may include a first synapse block and a second synapse block adjacent thereto, and the vertical neuron device unit may be formed at the same level as the first and second synapse blocks between the first synapse block and the second synapse block.

The plurality of synapse blocks may include a first synapse block and a second synapse block adjacent thereto, and the plurality of connection members may include a plurality of first connection members connecting a plurality of first electrode layers of the first synapse block and a plurality of first electrode layers of the second synapse block in a one-to-one manner.

The OTS device may be provided to be connected to each of the plurality of first connection members.

The plurality of synapse blocks may further include a third synapse block adjacent to the second synapse block, and the plurality of connection members may include a plurality of second connection members connecting a plurality of first vertical electrodes of the second synapse block and a plurality of first vertical electrodes of the third synapse blocks in a one-to-one manner.

The OTS device may be provided to be connected to each of the plurality of second connection members.

The neuron circuit portion may further include a signal amplifier.

The phase change material layer may include a first chalcogenide-based material, and the OTS device may include a second chalcogenide-based material as an OTS material.

Image data obtained from an image sensor may be input to an input unit of the neuromorphic device having the three-dimensional structure.

The neuromorphic device having the three-dimensional structure may be configured to receive an analog input value and output an analog output value, and may not include a digital-to-analog converter (DAC) and an analog-to-digital converter (ADC).

### Advantageous Effects

According to embodiments of the present invention, a neuromorphic device having a three-dimensional structure capable of equilibrium propagation neuromorphic calculation may be implemented. Therefore, a neuromorphic device according to embodiments may not use a digital-to-analog converter (DAC) and an analog-to-digital converter (ADC), and have significant advantages in terms of data processing time and energy/power consumption. The neuromorphic devices according to embodiments may not require additional circuits such as DAC and ADC, and thus may have advantages in terms of manufacturing processes and an occupied area.

In addition, according to embodiments of the present invention, it is possible to implement a neuromorphic device having a three-dimensional structure that may implement for high integration, simplifies the configuration of a neuron circuit portion, and may be easily manufactured by connecting synapse devices and a neuron circuit portion. In particular, the configuration of the neuron circuit portion may be simplified, and the synapse block and the neuron circuit portion may be easily manufactured in an integrated manner by using a synapse block containing a plurality of vertical phase change memory units and a neuron circuit portion containing an OTS (ovonic threshold switching) device.

Furthermore, according to embodiments of the present invention, it is possible to implement a neuromorphic device having a three-dimensional structure capable of performing efficient data processing for a predetermined input data such as image data. For example, since image data acquired from an image sensor may have a two-dimensional array form, and such image data may be easily input to the input unit of the neuromorphic device according to an embodiment of the present invention, the embodiment of the present invention may have significant advantages in image data processing.

However, the effects of the present invention are not limited to the above effects and may be expanded in various ways without departing from the technological spirit and scope of the present invention.

### BRIEF DESCRIPTION OF THE DRAWINGS

FIG. 1 is a perspective diagram illustrating a synapse block that may be applied to a neuromorphic device having a three-dimensional structure according to an embodiment of the present invention.

FIG. 2 is a perspective diagram for explaining the configuration of a neuron circuit portion which may be applied to a neuromorphic device having a three-dimensional structure according to an embodiment of the present invention.

FIG. 3 is a graph showing a switching characteristic of an ovonic threshold switching (OTS) device which may be applied to a neuromorphic device having a three-dimensional structure according to an embodiment of the present invention.

FIG. 4 is a circuit diagram showing a unit neuron device including antiparallel diodes according to a comparative example.

FIG. 5 is a perspective diagram for explaining a configuration of a neuron circuit portion that may be applied to a neuromorphic device having a three-dimensional structure according to another embodiment of the present invention.

FIG. 6 is a circuit diagram illustrating a circuit configuration which the signal amplifier of FIG. 5 may have.

FIG. 7 is a perspective diagram showing a neuromorphic device having a three-dimensional structure according to an embodiment of the present invention.

FIG. 8 is a diagram schematically illustrating an artificial neural network using a neuromorphic device having a three-dimensional structure according to an embodiment of the present invention.

FIG. 9 is a perspective view illustrating a neuromorphic device having a three-dimensional structure according to another embodiment of the present invention.

FIG. 10A to FIG. 10F are perspective views for explaining a manufacturing method of a neuromorphic device having a three-dimensional structure according to an embodiment of the present invention.

FIG. 11 is a diagram schematically illustrating a neuromorphic operation system (neuromorphic operation acceleration system) using a neuromorphic device according to an embodiment of the present invention.

### BEST MODE FOR CARRYING OUT THE INVENTION

Hereinafter, embodiments of the present invention will be described in detail with reference to the accompanying drawings.

The embodiments of the present invention to be described below are provided to more clearly explain the present invention to those skilled in the art, and the scope of the present invention is not limited by the following embodiments, and the embodiments may be modified in many different forms.

The terms used in this specification are used to describe specific embodiments and are not intended to limit the present invention. The terms indicating a singular form used herein may include plural forms unless the context clearly indicates otherwise. Also, as used herein, the terms, “comprise” and/or “comprising” specify the presence of the stated shape, step, number, operation, member, device, and/or group thereof and does not exclude the presence or addition of one or more other shapes, steps, numbers, operations, devices, devices and/or groups thereof. In addition, the term, “connection” used in this specification means not only a direct connection of certain members, but also a concept including an indirect connection in which other members are interposed between the members.

In addition, in the present specification, when a member is said to be located “on” another member, this arrangement includes not only a case in which a member is in contact with another member, but also a case where another member exists between the two members. As used herein, the term, “and/or” includes any one and all combinations of one or more of the listed items. In addition, the terms of degree such as “about” and “substantially” used in the present specification are used as a range of values or degrees, or as a meaning close thereof, taking into account inherent manufacturing and substance tolerances, and exact or absolute figures provided to aid in the understanding of this application are used to prevent the infringers from unfairly exploiting the stated disclosure.

Hereinafter, embodiments of the present invention will be described in detail with reference to the accompanying drawings. A size or a thickness of areas or parts shown in the accompanying drawings may be slightly exaggerated for clarity of the specification and convenience of description. The same reference numbers indicate the same configuring devices throughout the detailed description.

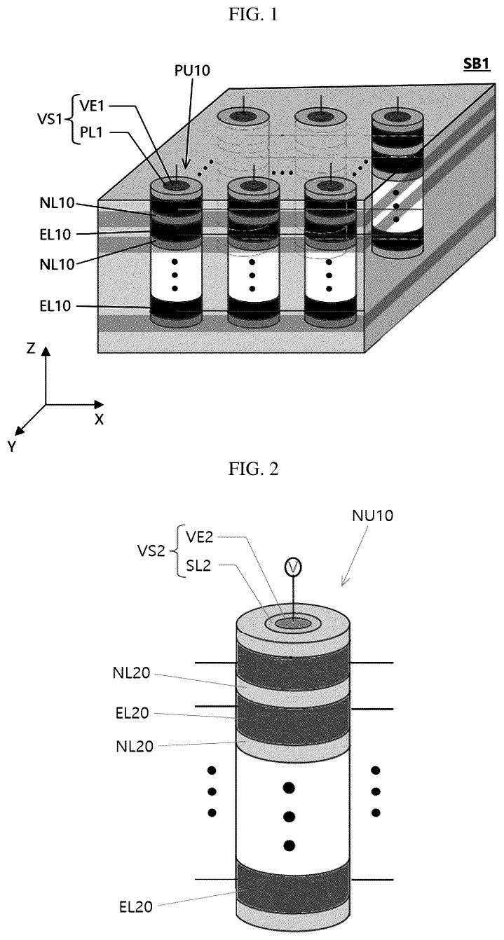

FIG. 1 is a perspective diagram illustrating a synapse block SB1 that may be applied to a neuromorphic device having a three-dimensional structure according to an embodiment of the present invention.

Referring to FIG. 1, a neuromorphic device having a three-dimensional structure according to an embodiment of the present invention may be a device capable of equilibrium propagation neuromorphic calculation. The neuromorphic device may include a plurality of synapse blocks, a plurality of connection members for electrically connecting the plurality of synapse blocks to each other, and a neuron circuit portion (neuron circuit unit) connected between the plurality of synapse blocks. Here, the neuron circuit portion may include an ovonic threshold switching (OTS) device.

FIG. 1 is a diagram illustrating a structure of one synapse block SB1. The synapse block SB1 may include a vertical phase-change random access memory (PRAM) structure, that is, a VPRAM structure. The synapse block SB1 may have a three-dimensional structure including a plurality of vertical phase change memory units PU10. The vertical phase change memory unit PU10 may include a first vertical structure VS1 including a first vertical electrode VE1 and a phase change material layer PL1 surrounding at least a portion of the first vertical electrode VE1, and a plurality of first electrode layers EL10 which are in contact with an outer peripheral surface of the first vertical structure VS1 and are spaced apart from each other in a vertical direction (i.e., Z-axis direction). A first insulating layer NL10 may be disposed between the plurality of first electrode layers EL10. The first insulating layer NL10 and the first electrode layer EL10 may be alternately and repeatedly stacked in the vertical direction while contacting the outer peripheral surface of the first vertical structure VS1. The first insulating layer NL10 and the first electrode layer EL10 may be alternately stacked while surrounding at least a portion of the outer peripheral surface of the first vertical structure VS1. The plurality of first electrode layers EL10 spaced apart in the vertical direction may be formed of the same material, but may not be formed of the same material. Furthermore, the plurality of first insulating layers NL10 spaced apart in the vertical direction may be formed of the same material, but may not be formed of the same material. The plurality of first electrode layers EL10 may be said to be a first group of electrode layer, and the plurality of first insulating layers NL10 may be said to be a first group of insulating layer.

According to one embodiment, each of the plurality of first electrode layers EL10 within one synapse block SB1 may have an expanded structure to be commonly applied to the plurality of vertical phase change memory units PU10. In other words, the first electrode layers EL10 existing at the same height (level) in the plurality of vertical phase change memory units PU10 may be connected to each other to form an integrated layer structure. Similarly, within one synapse block SB1, each of the plurality of first insulating layers NL10 may have an expanded structure to be commonly applied to the plurality of vertical phase change memory units PU10. In other words, the first insulating layers NL10 existing at the same height (level) in the plurality of vertical phase change memory units PU10 may be connected to each other to form an integrated layer structure. Accordingly, the synapse block SB1 may include the first insulating layer NL10 and the first electrode layer EL10 which are alternately stacked in the vertical direction while surrounding the outer peripheral surface of the plurality of first vertical structures VS1.

In one vertical phase change memory unit PU10, one cell (synapse cell) may be defined in an intersection region between one first electrode layer EL10 and the first vertical electrode VE1. Accordingly, a plurality of cells (synapse cells) spaced apart in the vertical direction may be defined in one vertical phase change memory unit PU10. The cell (synapse cell) may be defined by one first electrode layer EL10, one first vertical electrode VE1 crossing the first electrode layer EL10, and a region of the phase change material layer PL1 disposed between them. The synapse block SB1 may have a crossbar array structure where a vertical wiring (i.e., VE1) and a horizontal wiring (i.e., EL10) are crossing.

The cell (synapse cell) may be a type of memory cell and may have a plurality of resistance states. According to one example, the cell (synapse cell) may have three or more resistance states. For example, the cell (synapse cell) may have a plurality of resistance states which change analogously. The resistance state may be determined depending on the degree of phase change in the region of the phase change material layer PL1 corresponding to the cell. If necessary, programming may be performed for a plurality of cells (synapse cells). For example, programming of a selected cell may be performed by selecting one of the pluralities of first electrode layers EL10 and selecting one of the pluralities of first vertical electrodes VE1, and applying an electrical signal (voltage signal) between the selected first electrode layer EL10 and the selected first vertical electrode layer VE1.

According to one embodiment, a plurality of vertical phase change memory units PU10 may be arranged to form a plurality of rows and a plurality of columns. For example, the plurality of vertical phase change memory units PU10 may form M rows in a direction parallel to the X-axis direction and N columns in a direction parallel to the Y-axis direction. In other words, N units of the vertical phase change memory units PU10 may be arranged in one line in the X-axis direction, and M units of the vertical phase change memory units PU10 may be arranged in one line in the Y-axis direction. Meanwhile, L units of the first electrode layers EL10 may be arranged in the Z-axis direction. Therefore, in this case, the synapse block SB1 may have N×M×L cells (synapse cells).

However, the arrangement form of the plurality of vertical phase change memory units PU10, the structure of the first electrode layer EL10, the structure of the first insulating layer NL10, and the like which are described with reference to FIG. 1 may change in various ways.

FIG. 2 is a perspective diagram for explaining the configuration of a neuron circuit portion which may be applied to a neuromorphic device having a three-dimensional structure according to an embodiment of the present invention.

Referring to FIG. 2, a neuromorphic device having a three-dimensional structure according to an embodiment of the present invention may include a neuron circuit portion connected between a plurality of synapse blocks. The neuron circuit portion may include an ovonic threshold switching (OTS) device. The neuron circuit portion may include a vertical neuron device unit Nu10.

FIG. 2 is a diagram illustrating one vertical neuron device unit NU10. The vertical neuron device unit NU10 may include a second vertical structure VS2 including a second vertical electrode VE2 and an ovonic threshold switching (OTS) material layer SL2 surrounding at least a portion of the second vertical electrode VE2, and a plurality of second electrode layers EL20 which are in contact with an outer peripheral surface of the second vertical structure VS2 and are spaced apart from each other in a vertical direction. A second insulating layer NL20 may be disposed between the plurality of second electrode layers EL20. The second insulating layer NL20 and the second electrode layer EL20 may be alternately and repeatedly stacked in the vertical direction while contacting the outer peripheral surface of the second vertical structure VS2. The second insulating layer NL20 and the second electrode layer EL20 may be alternately stacked while surrounding at least a portion of the outer peripheral surface of the second vertical structure VS2. The plurality of second electrode layers EL20 spaced apart in the vertical direction may be formed of the same material, but may not be formed of the same material. Furthermore, the plurality of second insulating layers NL20 spaced apart in the vertical direction may be formed of the same material, but may not be formed of the same material. The plurality of second electrode layers EL20 may be said to be a second group of electrode layer, and the plurality of second insulating layers NL20 may be said to be a second group of insulating layer.

In one vertical neuron device unit NU10, one OTS device may be defined in an intersection region between one second electrode layer EL20 and the second vertical electrode VE2. Accordingly, a plurality of OTS devices spaced apart in the vertical direction may be defined in one vertical neuron device unit NU10. The OTS device may be defined by one second electrode layer EL20, one second vertical electrode VE2 crossing the second electrode layer EL20, and a region of the OTS material layer SL2 disposed between them. The one OTS device may correspond to one neuron device (unit neuron device).

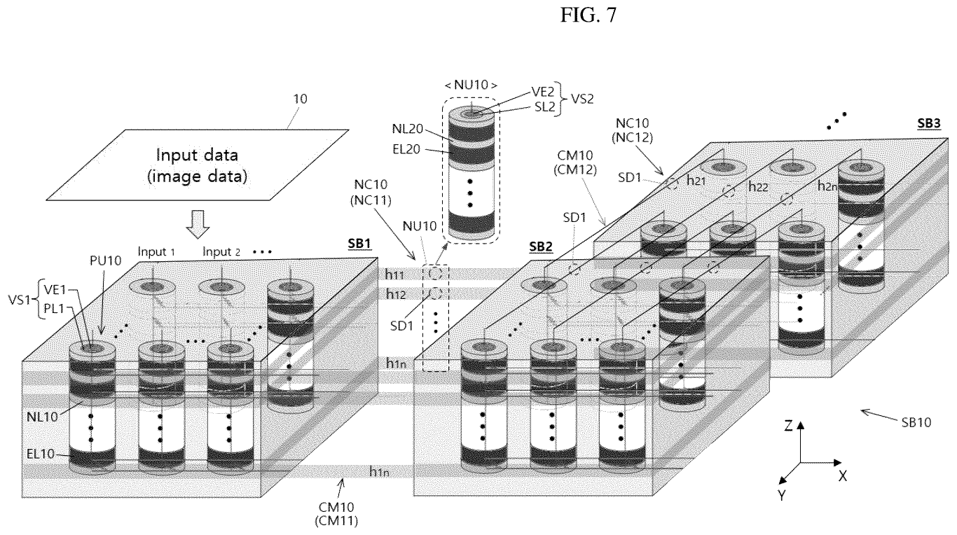

Each of the plurality of second electrode layers EL20 of the vertical neuron device unit NU10 may be electrically connected to each of the plurality of first electrode layers (EL10 in FIG. 1) of the vertical phase change memory unit (PU10 in FIG. 1) corresponding thereto. According to one embodiment, each of the plurality of second electrode layers EL20 of the vertical neuron device unit NU10 may be configured to be connected to each of the plurality of first electrode layers (EL10 of FIG. 1) of the corresponding vertical phase change memory unit (PU10 in FIG. 1) to form one body (integrated layer structure). This will be described in more detail later with reference to FIG. 7, etc.

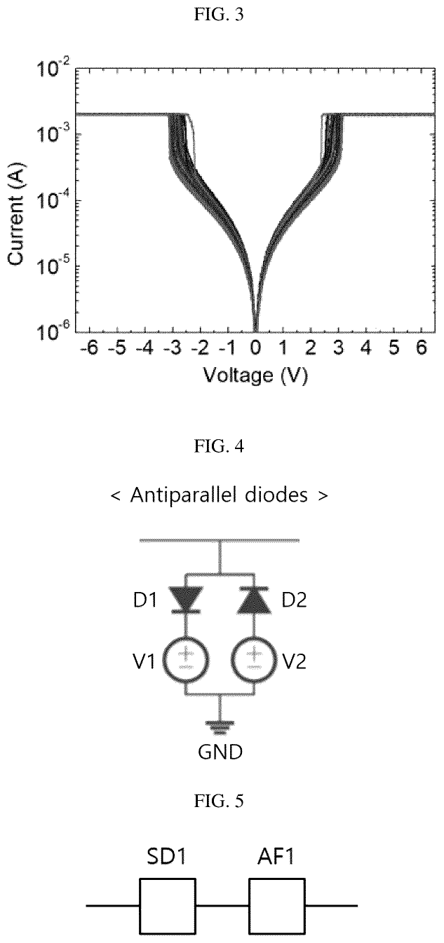

FIG. 3 is a graph showing a switching characteristic of an ovonic threshold switching (OTS) device which may be applied to a neuromorphic device having a three-dimensional structure according to an embodiment of the present invention.

Referring to FIG. 3, an OTS device which may be applied to a neuromorphic device according to an embodiment of the present invention may have a characteristic that switching occurs in both of the positive (+) direction and the negative (−) direction. The OTS device may be switched when a voltage higher than or equal to the threshold voltage is applied. The constant current that appears at both of a left end and a right end of the graph is the compliance current value in the measuring equipment, and measurement beyond that level may not be possible with the measuring equipment.

The OTS device may have characteristics similar to antiparallel diodes, that is, an antiparallel diode pair. In order to implement hardware that may perform the equilibrium propagation algorithm, programmable resistor devices for synapses and antiparallel diodes for adding nonlinearity to the network were required. Here, the antiparallel diodes are applied to a neuron circuit. A neuron circuit refers to the nodes placed between synapse groups in a neuromorphic device. There are various technological problems and difficulties in manufacturing a network device of a complex connection structure including the above-described programmable resistance devices and anti-parallel diodes. However, in embodiments of the present invention, the above-described technological problems and difficulties may be solved by replacing antiparallel diodes with the OTS device. The difficulties in integration may be solved when manufacturing a neuromorphic device having a three-dimensional structure by applying a synapse block having a VPRAM configuration and an OTS device together.

In neuron circuits, antiparallel diodes play a role in clipping an upper limit/a lower limit of the voltage of the neuron node. As the switching characteristics of the OTS device are similar to those of antiparallel diodes, the OTS device may perform the same or similar role as antiparallel diodes. One OTS device may replace the role of two diodes, and the OTS device may also be easily integrated in a vertical configuration with a synapse block having a VPRAM configuration. Therefore, it is possible to easily implement a neuron circuit part suitable for a synapse block having a three-dimensional structure by applying the OTS device.

FIG. 4 is a circuit diagram showing a unit neuron device including antiparallel diodes according to a comparative example.

Referring to FIG. 4, the unit neuron device according to the comparative example may include two diodes D1 and D2 arranged in an anti-parallel direction, that is, a first diode D1 and a second diode D2. Here, the first voltage source V1 may be connected to the first diode D1, and the second voltage source V2 may be connected to the second diode D2. The first and second voltage sources V1 and V2 may be connected to ground GND. It may not be easy to manufacture unit neuron devices including antiparallel diodes by applying them to a neuromorphic device having a three-dimensional structure.

FIG. 5 is a perspective diagram for explaining a configuration of a neuron circuit portion that may be applied to a neuromorphic device having a three-dimensional structure according to another embodiment of the present invention.

Referring to FIG. 5, in another embodiment of the present invention, the neuron circuit portion may include an OTS device SD1 and a signal amplifier AF1 connected to the OTS device SD1. The OTS device SD1 and the signal amplifier AF1 may be connected in series between two synapse blocks. The signal amplifier AF1 serves to amplify signals and may have a general signal amplification circuit configuration. The signal amplifier AF1 may be called as an amplifier circuit. The use of signal amplifier AF1 may be optional.

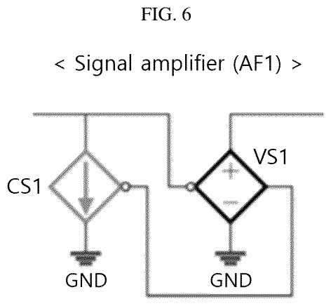

FIG. 6 is a circuit diagram illustrating a circuit configuration which the signal amplifier AF1 of FIG. 5 may have.

Referring to FIG. 6, the signal amplifier AF1 may have a circuit configuration as shown. The signal amplifier AF1 may include a current source CS1 and a voltage source VS1 connected thereto. The current source CS1 may be a current controlled current source (CCCS), and the voltage source VS1 may be a voltage-controlled voltage source (VCVS). The current source CS1 and the voltage source VS1 may each be connected to ground GND. However, the circuit configuration of the signal amplifier AF1 shown in FIG. 6 is merely illustrative and may be changed in various ways.

FIG. 7 is a perspective diagram showing a neuromorphic device having a three-dimensional structure according to an embodiment of the present invention.

Referring to FIG. 7, a neuromorphic device having a three-dimensional structure according to an embodiment of the present invention may be a device capable of equilibrium propagation neuromorphic calculation. The neuromorphic device may include a plurality of synapse blocks SB10, a plurality of connection members CM10 for electrically connecting the plurality of synapse blocks SB10 to each other, and a neuron circuit portion NC10 connected between the plurality of synapse blocks SB1.

Each of the plurality of synapse blocks SB10 may have a configuration as described with reference to FIG. 1 or a configuration similar thereto. Each of the plurality of synapse blocks SB10 may have a three-dimensional structure including a plurality of vertical phase change memory units PU10. The vertical phase change memory unit PU10 may include a first vertical structure VS1 including a first vertical electrode VE1 and a phase change material layer PL1 surrounding at least a portion of the first vertical electrode VE1, and a plurality of first electrode layers EL10 which are in contact with an outer peripheral surface of the first vertical structure VS1 and are spaced apart from each other in a vertical direction. A first insulating layer NL10 may be disposed between the plurality of first electrode layers EL10. The first insulating layer NL10 and the first electrode layer EL10 may be alternately and repeatedly stacked in the vertical direction while contacting the outer peripheral surface of the first vertical structure VS1. According to one embodiment, each of the plurality of first electrode layers EL10 within one synapse block SB1, SB2, and SB3 may have an expanded structure which is commonly applied to the plurality of vertical phase change memory units PU10.

The plurality of vertical phase change memory units PU10 in each of the plurality of synapse blocks SB10 may be arranged to form a plurality of rows and a plurality of columns. For example, a plurality of vertical phase change memory units PU10 may form M rows in a direction parallel to the X-axis direction and N columns in a direction parallel to the Y-axis direction. In other words, N units of the vertical phase change memory units PU10 may be arranged in one line in the X-axis direction, and M units of the vertical phase change memory units PU10 may be arranged in one line in the Y-axis direction. Meanwhile, L units of the first electrode layers EL10 may be arranged in the Z-axis direction. Therefore, in this case, each of the plurality of synapse blocks SB10 may have N×M×L cells (synapse cells).

The plurality of synapse blocks SB10 may include, for example, three or more synapse blocks. The plurality of synapse blocks SB10 may include a first synapse block SB1 and a second synapse block SB2 adjacent thereto. Furthermore, the plurality of synapse blocks SB10 may include a third synapse block SB3 adjacent to the second synapse block SB2. The second synapse block SB2 may be spaced apart from the first synapse block SB1 in a direction parallel to the X direction, and the third synapse block SB3 may be arranged to be spaced apart from the second synapse block SB2 in a direction parallel to the Y-axis. However, the positional relationship of the first to third synapse blocks SB1, SB2, and SB3 may change in various ways.

The plurality of connection members CM10 may include a plurality of first connection members CM11 connecting the first synapse block SB1 and the second synapse block SB2. For example, the plurality of first connection members CM11 may be configured to connect the plurality of first electrode layers EL10 of the first synapse block SB1 and the plurality of first electrode layers EL10 of the second synapse block SB2 in a one-to-one manner.

According to one embodiment, the plurality of first connection members CM11 may have a form of an electrode layer. Furthermore, each of the plurality of first connection members CM11 may be configured to be integrated with each of the plurality of first electrode layers EL10 of the first synapse block SB1 corresponding thereto. Furthermore, each of the plurality of first connection members CM11 may be configured to be integrated with each of the plurality of first electrode layers EL10 of the second synapse block SB2 corresponding thereto.

Furthermore, the plurality of connection members CM10 may include a plurality of second connection members CM12 connecting the second synapse block SB2 and the third synapse block SB3. For example, the plurality of second connection members CM12 may be configured to connect the plurality of first vertical electrodes VE1 of the second synapse block SB2 and the plurality of first vertical electrodes VE1 of the third synapse block SB3 in a one-to-one (1:1) manner.

According to one embodiment, each of the plurality of second connection members CM12 may have a wiring shape. In addition, the plurality of second connection members CM12 may be configured to connect the plurality of first vertical electrodes VE1 of the second synapse block SB2 and the plurality of first vertical electrodes VE1 of the third synapse block SB3 on the second synapse block SB2 and the third synapse block SB3.

The neuron circuit portion NC10 may include an ovonic threshold switching (OTS) device SD1. The neuron circuit portion NC10 may include a plurality of OTS devices SD1. The neuron circuit portion NC10 may include a first neuron circuit portion NC11 connecting the first synapse block SB1 and the second synapse block SB2. Furthermore, the neuron circuit portion NC10 may include a second neuron circuit portion NC12 connecting the second synapse block SB2 and the third synapse block SB3.

The neuron circuit portion NC10 may include a vertical neuron device unit NU10. For example, the first neuron circuit portion NC11 disposed between the first synapse block SB1 and the second synapse block SB2 may include the vertical neuron device unit NU10. The vertical neuron device unit NU10 may have the same configuration as described with reference to FIG. 2. The vertical neuron device unit NU10 may include a second vertical structure VS2 including a second vertical electrode VE2 and an OTS material layer SL2 surrounding at least a portion of the second vertical electrode VE2, and a plurality of second electrode layers EL20 which are in contact with an outer peripheral surface of the vertical structure VS2 and are spaced apart from each other in the vertical direction. A second insulating layer NL20 may be disposed between the plurality of second electrode layers EL20. The second insulating layer NL20 and the second electrode layer EL20 may be alternately and repeatedly stacked in the vertical direction while contacting the outer peripheral surface of the second vertical structure VS2.

Each of the plurality of second electrode layers EL20 of the vertical neuron device unit NU10 may be electrically connected to each of the plurality of first electrode layers EL20 of the vertical phase change memory unit NU10 corresponding to. In this embodiment, each of the plurality of second electrode layers EL20 of the vertical neuron device unit NU10 may be electrically connected to each of the plurality of first electrode layers EL20 of the first and second synapse blocks SB1 and SB2.

According to one embodiment, each of the plurality of second electrode layers EL20 of the vertical neuron device unit NU10 may be connected to each of the plurality of first electrode layers EL20 of the corresponding vertical phase change memory unit NU10 to form one body (integrated layer structure). In this embodiment, each of the plurality of second electrode layers EL20 of the vertical neuron device unit NU10 may be connected to each of the plurality of first electrode layers EL20 of the first and second synapse blocks SB1 and SB2 and may be integrated with each of the plurality of first electrode layers EL20. In this case, each of the plurality of second electrode layers EL20 of the vertical neuron device unit NU10 may be integrated with each of the plurality of first connection members CM11 corresponding thereto.

Furthermore, according to one embodiment, the vertical neuron device unit NU10 may be formed between the first synapse block SB1 and the second synapse block SB2 at the same level as them. Furthermore, one OTS device SD1 may be provided to be connected to each of the plurality of first connection members CM11. However, in some cases, the vertical neuron device unit NU10 may be formed at a different level from the first synapse block SB1 and the second synapse block SB2.

According to an embodiment of the present invention, since the vertical neuron device unit NU10 including a plurality of OTS devices SD1 is applied between two synapse blocks SB1, SB2 having a VPRAM configuration, it may be easy to manufacture the plurality of synapse blocks SB10 having a three-dimensional structure and the vertical neuron device unit NU10 having a three-dimensional structure together. In particular, since the phase change material layer PL1 applied to the synapse block SB10 and the OTS material layer SL2 applied to the vertical neuron device unit NU10 may be composed of similar materials, it may be easy to manufacture the synapse block SB10 and the vertical neuron device unit NU10 together. Furthermore, due to the structural similarity between the synapse block SB10 and the vertical neuron device unit NU10, it may be easy to manufacture the synapse block SB10 and the vertical neuron device unit NU10 together. In addition, since one OTS device SD1 may replace a unit neuron device including antiparallel diodes, the configuration of the neuron circuit portion NC10 may be simplified.

The OTS device SD1 may also be applied to the second neuron circuit portion NC12 connecting the second synapse block SB2 and the third synapse block SB3. For example, the OTS device SD1 may be provided to be connected to each of the plurality of second connection members CM12. The OTS device SD1 may be provided/disposed to be connected to an intermediate region of each of the plurality of second connection members CM12. The OTS device SD1 applied to the second neuron circuit portion NC12 may be equivalent to the OTS device SD1 applied to the first neuron circuit portion NC11. However, in terms of the stacked structure or specific form, the structure/shape of the OTS device SD1 applied to the second neuron circuit portion NC12 may be different from the structure/shape of the OTS device SD1 applied to the first neuron circuit portion NC11.

According to one embodiment, the phase change material layer PL1 applied to the synapse block SB10 may include a first chalcogenide-based material, and the OTS material layer SL2 applied to the OTS device SD1 may include a second chalcogenide-based material. The first chalcogenide-based material may be or include, for example, a GeSeTe-based material or a GeSbTe-based material. The first chalcogenide-based material may include, for example, a Ge—Se—Te compound or a Ge—Sb—Te compound. The second chalcogenide-based material may be or include, for example, a GeSe-based material. The second chalcogenide-based material may include, for example, a Ge—Se compound.

The plurality of first vertical electrodes VE1 of the first synapse block SB1 may form an input layer. Predetermined input data 10 may be input to the plurality of first vertical electrodes VE1 of the first synapse block SB1. The plurality of first electrode layers EL10 of the first synapse block SB1, the plurality of first connection members CM11, and the plurality of first electrode layers EL10 of the second synapse block SB2 may constitute a first hidden layer. The first hidden layer may be said to include a plurality of first hidden nodes (h₁₁, h₁₂, . . . , h₁ₙ). The plurality of first vertical electrodes VE1 of the second synapse block SB2, the plurality of second connection members CM12, and the plurality of first vertical electrodes VE1 of the third synapse block SB3 may constitute a second hidden layer. The second hidden layer may be said to include a plurality of second hidden nodes (h₂₁, h₂₂, . . . , h₂ₙ).

Although FIG. 7 illustrates three synapse blocks SB1, SB2, and SB3, three or more synapse blocks may be connected and arranged. A plurality of synapse blocks may be connected by alternately repeating the electrical connection between the first electrode layers between two adjacent synapse blocks and the electrical connection between the first vertical electrodes between two adjacent synapse blocks. Furthermore, the configuration of the neuron circuit portion may be applied between two adjacent synapse blocks.

According to one embodiment, the input data 10 may be image data obtained from an image sensor. In other words, image data obtained from an image sensor may be input to the input unit of the neuromorphic device having the three-dimensional structure. In this case, data may be individually input to each of the plurality of first vertical electrodes VE1 of the first synapse block SB1. According to an embodiment of the present invention, it is possible to implement a neuromorphic device having a three-dimensional structure capable of performing efficient data processing for a predetermined input data 10 such as image. In the case of image data acquired from an image sensor, it may have a two-dimensional array form, and since such image data may be easily input to the input unit of the neuromorphic device according to an embodiment of the present invention, the neuromorphic device may have a remarkable advantage in image data processing. However, the type of input data 10 is not limited to image data and may vary.

Furthermore, according to one embodiment, the neuromorphic device having the three-dimensional structure may be configured to receive an analog input value and output an analog output value, and may not include a digital-to-analog converter (DAC) and an analog-to-digital converter (ADC). A voltage signal may be input as the input value to the input node of the neuromorphic device, and a voltage signal may be output as the output value from the output node of the neuromorphic device. This process may be achieved by a mechanism in which the system reaches equilibrium (an equilibrium point) by input voltage. Accordingly, the neuromorphic device may be capable of equilibrium propagation neuromorphic operation and may not include a DAC and an ADC. Since the neuromorphic device does not use DAC and ADC, it may have a tremendous advantage in terms of data processing time and energy/power consumption.

The neuromorphic device according to the embodiment described in FIG. 7 may be implemented as a multi-layered ‘fully connected neural network’ structure having a three-dimensional structure.

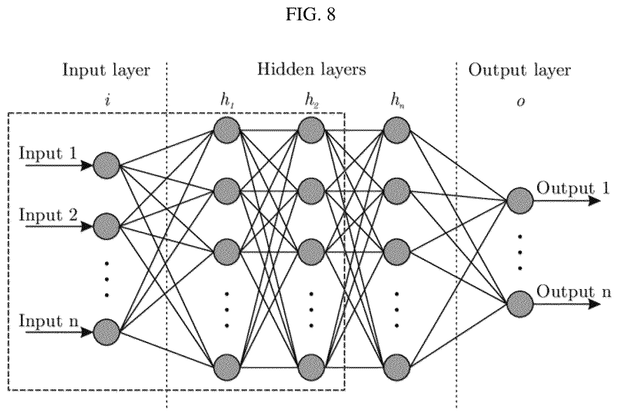

FIG. 8 is a diagram schematically illustrating an artificial neural network using a neuromorphic device having a three-dimensional structure according to an embodiment of the present invention.

Referring to FIG. 8, an artificial neural network to which a neuromorphic device having a three-dimensional structure according to an embodiment of the present invention is applied may include an input layer, an output layer, and a hidden layer disposed between them. A plurality of hidden layers may be disposed. The reference number h₁ represents a first hidden layer, h₂ represents a second hidden layer, and hₙ represents an nth hidden layer.

In FIG. 7 described in the foregoing descriptions, the plurality of first vertical electrodes VE1 of the first synapse block SB1 may constitute the input layer. The plurality of first electrode layers EL10 of the first synapse block SB1, the plurality of first connection members CM11, and the plurality of first electrode layers EL10 of the second synapse block SB2 may constitute the first hidden layer h₁. The plurality of first vertical electrodes VE1 of the second synapse block SB2, the plurality of second connection members CM12, and the plurality of first vertical electrodes VE1 of the third synapse block SB3 may constitute the second hidden layer h₂.

According to one embodiment of the present invention, in a 3D memory block, that is, a synapse block, the phase change memory PCM cells of each layer may be electrically connected through an electrode layer, and the vertical electrodes may be formed in the vertical direction so that connections may be made between the phase change memory cells. Therefore, when an input value enters the synapse block through a vertical electrode, the voltage of each electrode layer may be a voltage of the hidden layer. Conversely, when voltage is applied to each electrode layer, the voltage coming out of the vertical electrode may be the voltage transmitted to the next layer (e.g., the next hidden layer). Accordingly, the synapse blocks may be connected in a form where vertical electrode-horizontal electrode (electrode layer) connections are repeated, and may be implemented as a neural network of an arbitrary size.

Furthermore, the neuron circuit portion between the synapse blocks may include an OTS device, and if necessary, a system may be configured by adding a signal amplifier to the neuron circuit portion. The synapse system connected in such a manner may serve as an analog circuit capable of performing inference operations of equilibrium propagation. If image data is input as input data, inference may be implemented by measuring the output voltage of the final layer. In this process, no additional operation may be necessary, and a process that the system reaches equilibrium by the input voltage may be a process of inference.

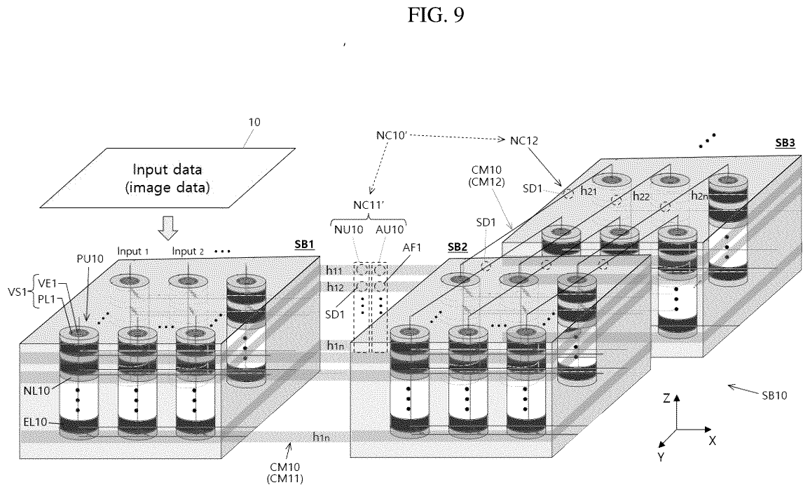

FIG. 9 is a perspective diagram illustrating a neuromorphic device having a three-dimensional structure according to another embodiment of the present invention.

Referring to FIG. 9, the neuromorphic device according to this embodiment may have a modified configuration from the neuromorphic device described in FIG. 7. In this embodiment, the neuron circuit portion NC10′ may include a first neuron circuit portion NC11′ and a second neuron circuit portion NC12. The first neuron circuit portion NC11′ may further include a signal amplifier AF1 connected to each of the plurality of OTS devices SD1. The OTS device SD1 and the signal amplifier AF1 may be connected in series between the first synapse block SB1 and the second synapse block SB2 in correspondence with each of the first electrode layer EL10. The OTS device SD1 and the signal amplifier AF1 may be connected in series between the first electrode layer EL10 of each of the first synapse block SB1 and the first electrode layer EL10 of each of the second synapse block SB2 corresponding thereto. It may be said that a plurality of signal amplifiers AF1 spaced apart from each other in a vertical direction constitute one signal amplifier unit AU10. The signal amplifier AF1 may have a separate circuit configuration electrically connected to the OTS device SD1. However, the use of signal amplifier AF1 may be optional.

In FIG. 9, a signal amplifier may not be applied to the second neuron circuit portion NC12, but may be applied depending on the case. When a signal amplifier is not applied to the second neuron circuit portion NC12, the second neuron circuit portion NC12 may be said to have a simple neuron circuit configuration (i.e., a simple OTS device configuration).

In FIG. 9, the remaining configuration excluding some configurations of the neuron circuit portion NC10′ may be the same or similar to that described in FIG. 7.

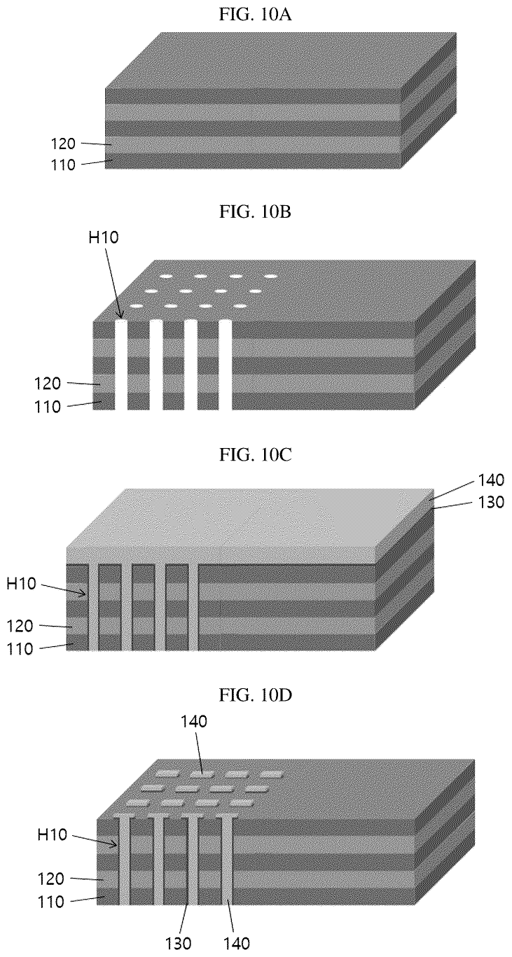

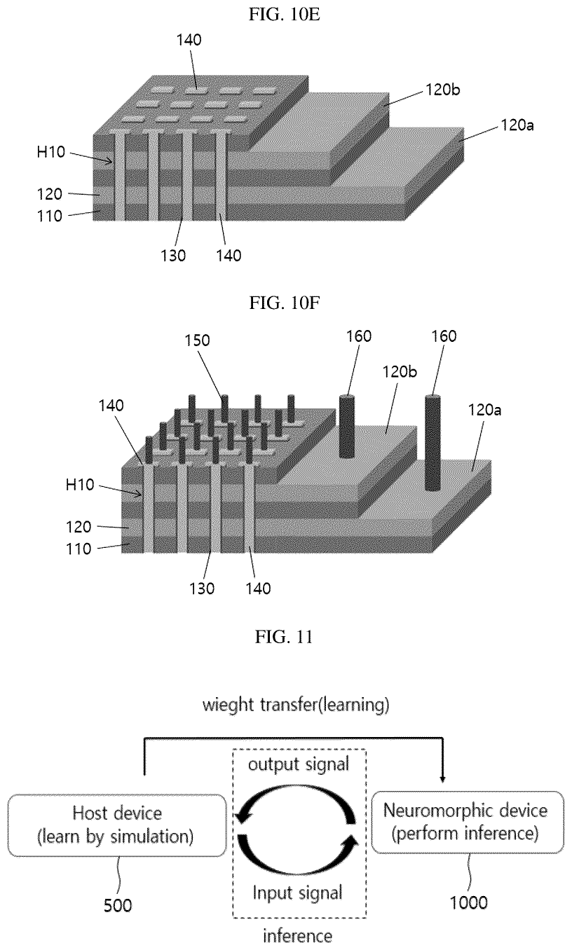

FIG. 10A to FIG. 10F are perspective views for explaining a manufacturing method of a neuromorphic device having a three-dimensional structure according to an embodiment of the present invention.

Referring to FIG. 10A, an insulating layer (a first insulating layer) 110 and an electrode layer (a first electrode layer) 120 may be alternately and repeatedly stacked on a predetermined substrate (not shown). Here, the insulating layer 110 may include at least any one of various insulating materials. For example, the insulating layer 110 may be formed of silicon oxide (e.g., SiO₂). The electrode layer 120 may include at least any one of various conductive materials. For example, the electrode layer 120 may be formed of TiN. However, the specific materials of the insulating layer 110 and the electrode layer 120 are merely examples, and each material may change in various ways.

Referring to FIG. 10B, a vertical hole H10 may be formed by etching a portion of a stack in which the insulating layer 110 and the electrode layer 120 are alternately stacked. A plurality of vertical holes H10 may be formed. For example, the plurality of vertical holes H10 may be arranged to form a plurality of rows and a plurality of columns.

Referring to FIG. 10C, a phase change material layer 130 and an electrode material layer 140 may be sequentially deposited on the stack in which the vertical hole H10 is formed. The phase change material layer 130 may be formed to conformally cover the inner surface of the vertical hole H10 and the upper surface of the stack. The phase change material layer 130 may be formed to a thin thickness, and for example, may be formed through an atomic layer deposition (ALD) process. The electrode material layer 140 may be formed on the phase change material layer 130 and may be formed to fill the vertical hole H10. The electrode material layer 140 may be formed to include at least any one of various conductive materials. As an example, the electrode material layer 140 may include TiN, but the material may change in various ways.

Referring to FIG. 10D, the electrode material layer 140 and the phase change material layer 130 may be patterned. The electrode material layer 140 and the phase change material layer 130 may be removed by etching around each vertical hole H10. The phase change material layer 130 and the electrode material layer 140 may remain inside and above the vertical hole H10. The electrode material layer 140 remaining inside and above the vertical hole H10 may be referred to as a vertical electrode (first vertical electrode). Hereinafter, the reference number 140 is referred to as a vertical electrode. The phase change material layer 130 may be provided to surround the vertical electrode 140. Each vertical electrode 140 and the phase change material layer 130 surrounding it may constitute a vertical structure (first vertical structure).

Referring to FIG. 10E, a portion of the stack in which the insulating layer 110 and the electrode layer 120 are alternately stacked may be etched in a step shape to expose an upper surface of each electrode layer 120. Here, the electrode layer 120 exposed in a lower side may be referred to as a 1 -1 electrode layer 120a, and the electrode layer 120 exposed above the 1 -1 electrode layer 120 a may be referred to as a 1-2 electrode layer 120 b.

Referring to FIG. 10F, a first contact plug 150 in contact with the vertical electrode 140, and a second contact plug 160 in contact with the electrode layers 120a and 120b may be formed. A plurality of first contact plugs 150 may be formed in contact with the plurality of vertical electrodes 140, and a plurality of second contact plugs 160 may be formed in contact with the plurality of electrode layers 120a and 120b. Although not shown, a plurality of first wires connected to the plurality of first contact plugs 150 may be further provided, and a plurality of second wires connected to the plurality of second contact plugs 160 may be further provided.

A programming operation for the plurality of cells (synapse cells) may be performed by applying an electrical signal to the plurality of cells (synapse cells) through the plurality of first contact plugs 150 and the plurality of second contact plugs 160. For example, programming of a selected cell may be performed by selecting one of the pluralities of first contact plugs 150 and one of the pluralities of second contact plugs 160, and applying a signal (voltage signal) between the selected vertical electrode 140 and the selected electrode layer 120. Accordingly, here, the plurality of second contact plugs 160 may be contact elements for at least a programming operation. In addition, the plurality of first contact plugs 150 may be used as input nodes for inputting input data.

The manufacturing method of a synapse block described with reference to FIGS. 10A to 10F is merely an example, and this method may be modified in various ways. Furthermore, while forming a plurality of synapse blocks on a substrate, a neuron device portion connected thereof may be formed. When forming at least two synapse blocks and at least one first neuron device portion, a masking process may be applied. Furthermore, a second neuron device portion may be formed above or below at least two synapse blocks. In addition, the manufacturing method of the above-described neuromorphic device may change in various ways.

FIG. 11 is a diagram schematically illustrating a neuromorphic operation system (neuromorphic operation acceleration system) using a neuromorphic device according to an embodiment of the present invention.

Referring to FIG. 11, the neuromorphic device 1000 according to an embodiment of the present invention may be used for off-line learning and may operate by transferring learned synapse information to memory. Synapse values found through simulation in an external host device 500 may be written, that is, programmed, into the memory of the neuromorphic device 1000, that is, a synapse block. After transferring the synapse values learned through circuit simulation to the neuromorphic device 1000, the neuromorphic device 1000 may be applied to neuromorphic calculation. Here, the host device 500 may include, for example, a field programmable gate array (FPGA), but is not limited thereof. The types of host device 500 may vary. The neuromorphic device 1000 may operate to perform, for example, an inference operation.

In order to confirm the actual performance of the neuromorphic device according to an embodiment of the present invention, the MNIST (Modified National Institute of Standards and Technology) learning accuracy was obtained through circuit simulation based on SPICE (Simulation Program with Integrated Circuit Emphasis). It showed a high performance of over 95%. Neuromorphic devices using 3D VPRAM according to embodiments of the present invention have the advantages such as low power and high integration, and may be usefully used in various fields.

According to the embodiments of the present invention described above, a neuromorphic device having a three-dimensional structure capable of equilibrium propagation neuromorphic calculation may be implemented. Therefore, neuromorphic devices according to embodiments may not use a digital-to-analog converter (DAC) and an analog-to-digital converter (ADC), and have remarkable advantages in terms of data processing time and energy/power consumption. Since the neuromorphic devices according to embodiments may not require additional circuits such as DAC and ADC, they may have advantages in terms of manufacturing processes and an occupying area. In addition, according to embodiments of the present invention, it is possible to implement a neuromorphic device having a three-dimensional structure that may implement for high integration, simplifies the configuration of a neuron circuit portion, and may be easily manufactured by connecting synapse devices and the neuron circuit portion. In particular, the configuration of the neuron circuit portion may be simplified, and the synapse block and neuron circuit portion may be easily manufactured by using an integrated method since a synapse block containing a plurality of vertical phase change memory units, and a neuron circuit portion containing an OTS (ovonic threshold switching) device are used. Furthermore, according to embodiments of the present invention, it is possible to implement a neuromorphic device having a three-dimensional structure capable of performing efficient data processing for a predetermined input data such as image data. For example, since image data acquired from an image sensor may have a two-dimensional array form, and such image data may be easily input to the input unit of the neuromorphic device according to an embodiment of the present invention, it may have tremendous advantages for an image data processing.

In this specification, the preferred embodiments of the present invention have been disclosed, and although specific terms have been used, they are only used in a general sense to easily explain the technological content of the present invention and to help understanding the present invention, and they are not used to limit the scope of the present invention. It is obvious to those having ordinary skill in the related art to which the present invention belong that other modifications based on the technological idea of the present invention may be implemented in addition to the embodiments disclosed herein. It will be understood to those having ordinary skill in the related art that in connection with neuromorphic devices having a three-dimensional structure and manufacturing methods thereof according to the embodiments described with reference to FIGS. 1 to 11, various substitutions, changes, and modifications may be made without departing from the technological spirit of the present invention. Therefore, the scope of the invention should not be determined by the described embodiments, but should be determined by the technological concepts described in the claims.

### INDUSTRIAL APPLICABILITY

The embodiments of the present invention may be applied to electronic devices, manufacturing methods thereof, and their use. The embodiments of the present invention may be applied to neuromorphic devices, manufacturing methods thereof, and their use.

1. A neuromorphic device having a three-dimensional structure capable of equilibrium propagation neuromorphic calculation, comprising:
a plurality of synapse blocks each having a three-dimensional structure including a plurality of vertical phase change memory units, wherein the vertical phase change memory unit includes a first vertical structure including a first vertical electrode and a phase change material layer surrounding at least a portion of the first vertical electrode, and a plurality of first electrode layers spaced apart from each other in a vertical direction while contacting an outer peripheral surface of the first vertical structure;
a plurality of connection members for electrically connecting the plurality of synapse blocks to each other; and
a neuron circuit portion connected between the plurality of synapse blocks and including an ovonic threshold switching (OTS) device.

2. The neuromorphic device having a three-dimensional structure of claim 1, wherein in each of the plurality of synapse blocks, the plurality of vertical phase change memory units are arranged to form a plurality of rows and a plurality of columns.

3. The neuromorphic device having a three-dimensional structure of claim 1, wherein the neuron circuit portion includes a vertical neuron device unit.

4. The neuromorphic device having a three-dimensional structure of claim 3, wherein the vertical neuron device unit includes a second vertical electrode, a second vertical structure including an ovonic threshold switching (OTS) material layer surrounding at least a portion of the second vertical electrode, and a plurality of second electrode layers spaced apart from each other in a vertical direction while contacting with an outer peripheral surface of the second vertical structure.

5. The neuromorphic device having a three-dimensional structure of claim 4, wherein each of the plurality of first electrode layers of the vertical phase change memory unit is electrically connected to each of the plurality of second electrode layers of the vertical neuron device unit corresponding thereto.

6. The neuromorphic device having a three-dimensional structure of claim 4, wherein each of the plurality of first electrode layers of the vertical phase change memory unit is connected to each of the plurality of second electrode layers of the corresponding vertical neuron device unit to form one body.

7. The neuromorphic device having a three-dimensional structure of claim 3,
wherein the plurality of synapse blocks include a first synapse block and a second synapse block adjacent thereto,
wherein the vertical neuron device unit is formed at the same level as the first and second synapse blocks between the first synapse block and the second synapse block.

8. The neuromorphic device having a three-dimensional structure of claim 1,
wherein the plurality of synapse blocks include a first synapse block and a second synapse block adjacent thereto,
wherein the plurality of connection members include a plurality of first connection members connecting a plurality of first electrode layers of the first synapse block and a plurality of first electrode layers of the second synapse block in a one-to-one manner.

9. The neuromorphic device having a three-dimensional structure of claim 8, wherein the OTS device is provided to be connected to each of the plurality of first connection members.

10. The neuromorphic device having a three-dimensional structure of claim 8,
wherein the plurality of synapse blocks further include a third synapse block adjacent to the second synapse block,
wherein the plurality of connection members include a plurality of second connection members connecting a plurality of first vertical electrodes of the second synapse block and a plurality of first vertical electrodes of the third synapse blocks in a one-to-one manner.

11. The neuromorphic device having a three-dimensional structure of claim 10, wherein the OTS device is provided to be connected to each of the plurality of second connection members.

12. The neuromorphic device having a three-dimensional structure of claim 1, wherein the neuron circuit portion further includes a signal amplifier.

13. The neuromorphic device having a three-dimensional structure of claim 1,
wherein the phase change material layer includes a first chalcogenide-based material,
wherein the OTS device includes a second chalcogenide-based material as an OTS material.

14. The neuromorphic device having a three-dimensional structure of claim 1, wherein the neuromorphic device is configured so that image data obtained from an image sensor is input to an input unit of the neuromorphic device having the three-dimensional structure.

15. The neuromorphic device having a three-dimensional structure of claim 1, wherein the neuromorphic device is configured to receive an analog input value and output an analog output value, and does not include a digital-to-analog converter (DAC) and an analog-to-digital converter (ADC).
